(19) United States
(12) Patent Application Publication
(10) Pub. No.: US 2025/0191950 A1
(43) Pub. Date: Jun. 12, 2025

(54) SUBSTRATE PROCESSING APPARATUS AND SUBSTRATE PROCESSING SYSTEM

(71) Applicant: SCREEN Holdings Co., Ltd., Kyoto (JP)

(72) Inventor: Takanori HIRAI, Kyoto-shi (JP)

(21) Appl. No.: 18/965,121

(22) Filed: Dec. 2, 2024

(30) Foreign Application Priority Data
Dec. 6, 2023 (JP) 2023-206291

(51) Int. Cl. H01L 21/677; B05C 5/02; B05C 21/00; H01L 21/67

(52) U.S. Cl. CPC H01L 21/67748; B05C 5/0254; B05C 21/00; H01L 21/67173

(57) ABSTRACT

A substrate processing apparatus includes a coater and a plurality of post-processors. The coater is configured to perform the coating process at a position separated from a substrate loader/unloader in a first horizontal direction. The post-processors are configured to perform a predetermined post-process on the substrate after being subjected to the coating process. The substrate is transported back and forth along a linear transport path formed between the substrate loader/unloader and the coater. The post-processors are arranged separately with respect to the transport path in the second horizontal direction perpendicular to the first horizontal direction. As a result, the compactness of the substrate processing apparatus is achieved in the first horizontal direction and the second horizontal direction.

### CROSS REFERENCE TO RELATED APPLICATION

The disclosure of Japanese Patent Application No. 2023-206291 filed on Dec. 6, 2023 including specification, drawings and claims is incorporated herein by reference in its entirety.

### BACKGROUND OF THE INVENTION

### 1. Field of the Invention

The present invention relates to a substrate processing apparatus and a substrate processing system that perform a coating process of applying processing liquids to substrates for semiconductor packages such as substrates for fan out wafer level packages (FOWLPs), glass substrates for liquid crystal display devices, semiconductor substrates, glass substrates for PDPs, glass substrates for photomasks, substrates for color filters, substrates for recording disks, substrates for solar cells, substrates for precision electronic devices such as substrates for electronic paper, rectangular glass substrates, flexible substrates for film liquid crystals, and substrates for organic EL (these substrates will hereinafter be called “substrates” simply).

### 2. Description of the Related Art

A semiconductor device is manufactured by processes including a coating process of forming a coating film on a substrate surface by applying a processing liquid to the substrate surface. In the field of semiconductor devices, demands for size reduction and thickness reduction have been growing increasingly in recent years. To fulfill these demands, attention has been focused on FOWLP technology by which highly integrated semiconductors are solely surface-mounted on a printed board. For manufacturing high-quality products, the significance of the coating process has also been increasing in relation to the FOWLP technology. In this regard, a coating device shown in Japanese Patent Application Laid-Open No. 2022-131177 is suggested, for example.

### SUMMARY OF INVENTION

A substrate with a coating film formed by the coating device is subjected to post-processes such as a vacuum drying process using a vacuum drying device, a drying process by heating using a heating plate, and a cooling process using a cooling plate. According to the FOWLP technology, a pre-process is additionally performed in some cases such as a dehydration baking process for removing moisture from the printed board. In this regard, a substrate processing apparatus has been suggested that is capable of performing processes such as a vacuum drying process, a heating process, a cooling process, and a dehydration baking process in combination in addition to a coating process. In a substrate processing apparatus suggested as an example, a dehydration baking device, a coating device, a vacuum drying device, a heating device for post-baking, and a cooling device are arranged linearly, processes such as a dehydration baking process and a coating process are performed on a substrate at the corresponding devices while the substrate is transported between these devices using a transport device such as a conveyor. There is also a suggested substrate processing system where equipment front end modules (EFEMs) are arranged on both sides of such a substrate processing apparatus, and the substrate is loaded automatically into the substrate processing apparatus and the substrate is unloaded automatically from the substrate processing apparatus.

In the above suggested examples (substrate processing apparatus and substrate processing system), a pre-processing device such as the dehydration baking device and a post-processing device such as that for the vacuum drying process are arranged in line with the coating device. This makes size increase of the substrate processing apparatus or that of the substrate processing system unavoidable in a direction of the arrangement, resulting in enlargement of a footprint.

The present invention has been made in view of the foregoing problems, and is intended to reduce enlargement of a foot print in a substrate processing apparatus and a substrate processing system that perform not only application of a processing liquid to a substrate but also a predetermined post-process after implementation of the coating process.

One aspect of this invention is directed to a substrate processing apparatus that performs a coating process of applying a processing liquid to a substrate received from a substrate loader/unloader. The apparatus comprises: a coater configured to perform the coating process at a position separated from the substrate loader/unloader in a first horizontal direction; a plurality of post-processors configured to perform a predetermined post-process on the substrate after being subjected to the coating process; and a substrate transporter configured to transport the substrate back and forth in the first horizontal direction between the substrate loader/unloader and the coater along a transport path extending in the first horizontal direction, and configured to be responsive to each of the post-processors to stop temporarily at a position along the transport path and facing the post-processor and allow the substrate to be transferred to and from the post-processor, wherein the post-processors are arranged separately with respect to the transport path in a second horizontal direction perpendicular to the first horizontal direction, and the substrate transporter transports the substrate received from the substrate loader/unloader to the coater and then to the post-processors, and thereafter transfers the substrate to the substrate loader/unloader.

Other aspect of the invention is a substrate processing system comprising: a substrate loader/unloader configured to load and unload of a substrate; and the substrate processing apparatus.

According to the invention having the foregoing configuration, the coater is arranged face-to-face with the substrate loader/unloader such as an EFEM in the first horizontal direction, and the substrate is transported back and forth along the linear transport path formed between the substrate loader/unloader and the coater. Furthermore, the post-processors are arranged separately with respect to the transport path in the second horizontal direction perpendicular to the first horizontal direction. As a result, the compactness of the substrate processing apparatus is achieved in the first horizontal direction and the second horizontal direction.

As described above, it is possible to reduce enlargement of a footprint in a substrate processing apparatus and a substrate processing system equipped with the substrate processing apparatus that perform not only application of a processing liquid to a substrate but also a predetermined post-process after the coating process.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1 is a perspective view schematically showing a substrate processing system equipped with a first embodiment of a substrate processing apparatus according to the present invention.

FIG. 2 is a plan view schematically showing the substrate processing system in FIG. 1.

FIG. 3 is a perspective view schematically showing the configuration of the coater in FIG. 2.

FIGS. 4A to 4D are schematic views showing a procedure of the transport of the substrate and the processes on the substrate performed by the substrate processing apparatus in FIGS. 1 and 2.

FIG. 5 is a perspective view schematically showing a substrate processing system equipped with a second embodiment of a substrate processing apparatus according to the present invention.

FIG. 6 is a perspective view schematically showing a substrate processing system equipped with a third embodiment of a substrate processing apparatus according to the present invention.

FIG. 7 is a perspective view schematically showing a substrate processing system equipped with a fourth embodiment of a substrate processing apparatus according to the present invention.

### DETAILED DESCRIPTION OF THE PREFERRED EMBODIMENTS

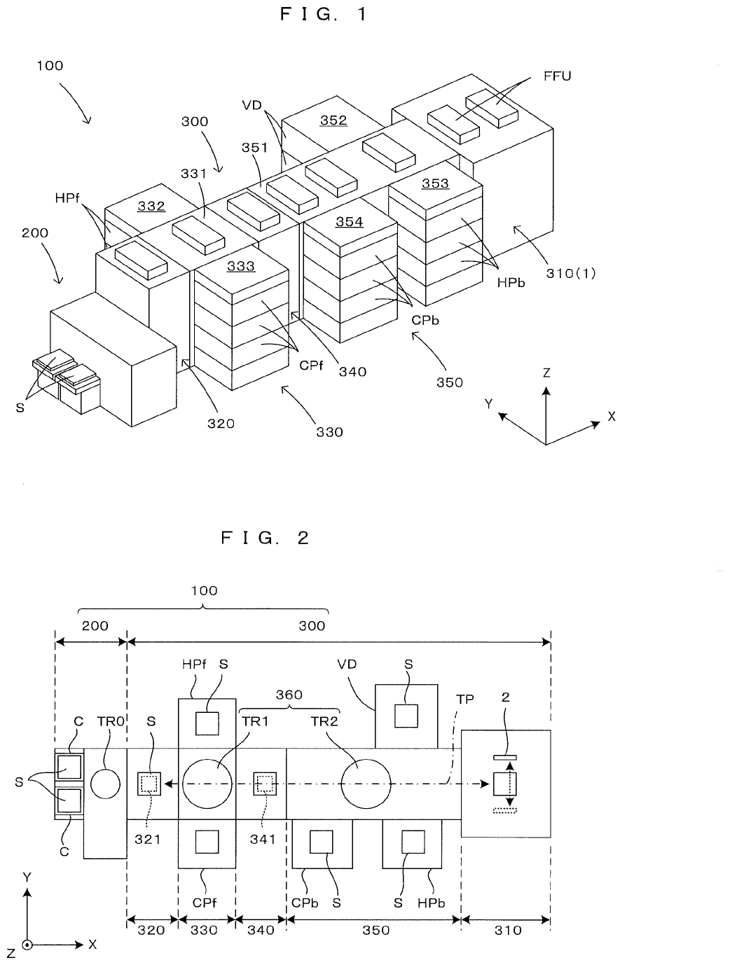

FIG. 1 is a perspective view schematically showing a substrate processing system equipped with a first embodiment of a substrate processing apparatus according to the present invention. FIG. 2 is a plan view schematically showing the substrate processing system in FIG. 1. A substrate processing system 100 includes a substrate loader/unloader 200 that loads and unloads a substrate S, and a substrate processing apparatus 300 that performs a coating process of applying a processing liquid to the substrate S received from the substrate loader/unloader 200. The substrate loader/unloader 200 has a mechanism for transferring a cassette C provided at a front surface thereof. The substrate loader/unloader 200 has a transport robot TR0. The transport robot TR0 has the function of extracting the substrate S stored in the cassette C and transferring the substrate S to the substrate processing apparatus 300, and the function of receiving the substrate S after being subjected to the coating process by the substrate processing apparatus 300 and returning the substrate S to the cassette C. In the present specification, to show each part forming the substrate processing system 100 clearly in terms of its arrangement, motion, etc., a coordinate system is given in appropriate cases where a vertical direction is represented as a Z axis and a horizontal plane is represented as an XY plane. In each coordinate system, a direction in which an arrow tip is pointing is represented as a + (positive) direction, and a direction opposite thereto is represented as a − (negative) direction.

The substrate processing apparatus 300 is arranged next to the substrate loader/unloader 200 and in the (+X) direction with respect to the substrate loader/unloader 200. The substrate processing apparatus 300 includes a coating unit 310 arranged at a position separated toward the (+X) direction from the substrate loader/unloader 200. A first standby unit 320, a pre-processing unit 330, a second standby unit 340, and a post-processing unit 350 are arranged in this order in the (+X) direction between the substrate loader/unloader 200 and the coating unit 310. As indicated by a dash-dotted line in FIG. 2, a linear transport path TP is extended in the X direction inside these units. Furthermore, a substrate transporter 360 (FIG. 2) for moving the substrate S back and forth along the transport path TP is provided inside the substrate processing apparatus 300.

As shown in FIG. 1, at the coating unit 310, a coater 1 is arranged in internal space where clean air fed from fan filter units FFU mounted on a ceiling surface generates a downflow. The coater 1 moves in the Y direction while ejecting the processing liquid from a slit nozzle to supply the processing liquid to a surface of the substrate S, thereby forming a coating film. Such generation of a downflow of clean air in internal space also applies to the first standby unit 320, the pre-processing unit 330, the second standby unit 340, and the post-processing unit 350 described later.

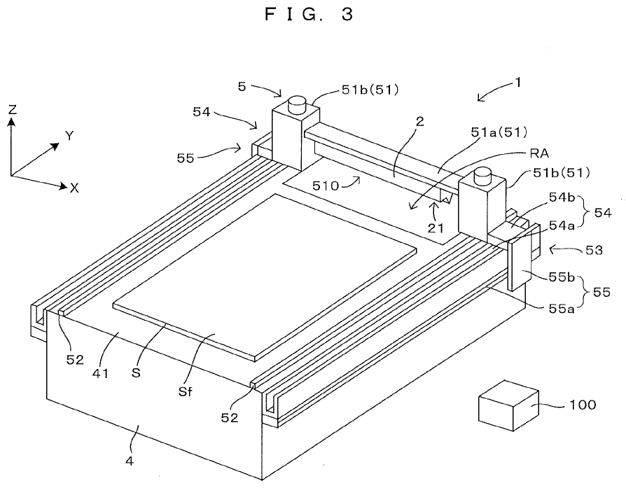

FIG. 3 is a perspective view schematically showing the configuration of the coater in FIG. 2. The coater 1 has a configuration basically the same as that of the coating device shown in Japanese Patent Application Laid-Open No. 2022-131177. Thus, in the present specification, only a principal part of the coater 1 will be described.

The coater 1 is a coating device called a slit coater that applies the processing liquid to a surface Sf of the substrate S as an example of a coating target using a slit nozzle 2 (hereinafter called a “nozzle 2” simply). In the present specification, of both main surfaces of the substrate S, “the surface Sf of the substrate S” means a main surface to be coated with the processing liquid.

The coater 1 includes a stage 4 allowing the substrate S to be held thereon under suction in a horizontal posture, and a coating processor 5 that performs the coating process using the nozzle 2 on the substrate S held on the stage 4. The stage 4 is formed of stone such as granite having a shape like a rectangular solid, and has a holding surface 41 formed at a part of an upper surface thereof on the side of the (−Y) direction. The holding surface 41 is processed into a practically horizontal plane surface and used for holding the substrate S thereon having been transported along the transport path TP by the substrate transporter 360. The substrate S is placed onto the holding surface 41 via a lift pin not shown in the drawings. The holding surface 41 has a large number of vacuum suction openings not shown in the drawings formed separately from each other. By sucking the substrate S through the vacuum suction openings, the substrate S is held horizontally at a predetermined position during the coating process. This is not the only configuration for holding the substrate S. In one configuration, the substrate S may be held mechanically, for example. At the stage 4, a nozzle adjustment region RA is provided closer to the (+Y) direction than a region occupied by the holding surface 41 and a nozzle maintenance unit (not shown in the drawings) is arranged in the nozzle adjustment region RA.

The nozzle 2 is extended in the X direction. The nozzle 2 has a lower end portion (nozzle lip portion) formed into a downwardly tapered shape along a YZ section. At this lower end portion, a slit-like ejection opening 21 is extended in the X direction and the processing liquid fed under pressure from a processing liquid supplier not shown in the drawings is ejected from the ejection opening 21 onto the surface Sf of the substrate S. As a result, the surface Sf of the substrate S is coated with the processing liquid.

The coating processor 5 has a nozzle support 51 supporting the nozzle 2. The nozzle support 51 has a support member 51a provided above the stage 4 and extended parallel to the X direction, and two up-down mechanisms 51b for supporting the support member 51a from both sides in the X direction and moving the support member 51a up and down. The support member 51a is a rod member made of carbon fiber reinforced resin, for example, and having a rectangular section. The support member 51a has a lower surface functioning as an attachment part 510 for the nozzle 2. The support member 51a supports the nozzle 2 in a manner attachable to and removable from the attachment part 510. Various types of fastening mechanisms such as a latch or a screw are available, as appropriate, as a mechanism for attaching and removing the nozzle 2 to and from the attachment part 510 of the support member 51a.

The two up-down mechanisms 51b are coupled to corresponding end portions of the support member 51a in a lengthwise direction thereof, and have respective AC servo motors, ball screws, etc. The support member 51a and the nozzle 2 fixed to the support member 51a are moved up and down in the vertical direction (Z direction) by the up-down mechanisms 51b to adjust an interval between the ejection opening 21 formed at the lower end of the nozzle 2 and the substrate S, namely, the height of the ejection opening 21 relative to the substrate S. The position of the support member 51a in the vertical direction is detectable using a linear encoder not shown in the drawings composed of a scaling part provided at a side surface of each of the up-down mechanisms 51b and a detection sensor provided at a side surface of the nozzle 2, for example, in such a manner as to face the scaling part.

As shown in FIG. 3, the nozzle support 51 having the foregoing configuration has a bridge structure stretched between the right and left opposite end portions of the stage 4 in the X direction and bridging over the holding surface 41. The coating processor 5 has a slit nozzle moving unit 53 that moves the nozzle support 51 in the Y direction. The slit nozzle moving unit 53 functions as a relative moving unit for moving the nozzle support 51 as the bridge structure and the nozzle 2 supported by the nozzle support 51 in the Y direction relative to the substrate S held on the stage 4. More specifically, the slit nozzle moving unit 53 has a guide rail 52 along which the movement of the nozzle 2 is guided in the Y direction, a linear motor 54 as a drive source, and a linear encoder 55 for detecting the position of the ejection opening 21 of the nozzle 2 that are provided on each of the +X side and the −X side.

The two guide rails 52 are provided at the corresponding opposite end portions of the stage 4 in the X direction, and are extended in the Y direction in such a manner as to cover a zone where the nozzle adjustment region RA and the holding surface 41 are provided. The two guide rails 52 guide the movements of the corresponding two up-down mechanisms 51b in the Y direction. The two linear motors 54 are AC coreless linear motors provided at the corresponding opposite sides of the stage 4 and each having a stator 54a and a mover 54b. The stator 54a is arranged at a side surface of the stage 4 in the X direction in such a manner as to extend in the Y direction. The mover 54b is fixed externally to the up-down mechanism 51b. The two linear motors 54 drive the corresponding two up-down mechanisms 51b in the Y direction using magnetic forces generated between the corresponding stators 54a and movers 54b.

Each linear encoder 55 has a scaling part 55a and a detector 55b. The scaling part 55a is provided at the bottom of the stator 54a of the linear motor 54 fixed to the stage 4, and is extended in the Y direction. The detector 55b is fixed still externally to the mover 54b of the linear motor 54 fixed to the up-down mechanism 51b, and is arranged face-to-face with the scaling part 55a. The linear encoder 55 detects the position of the ejection opening 21 of the nozzle 2 in the Y direction on the basis of the positions of the scaling part 55a and the detector 55b relative to each other.

The slit nozzle moving unit 53 having the above-described configuration drives the nozzle support 51 in the Y direction, thereby allowing the nozzle 2 to move between a position above the nozzle adjustment region RA and a position above the substrate S held on the stage 4. The coater 1 moves the nozzle 2 relative to the substrate S while ejecting the processing liquid from the ejection opening 21 of the nozzle 2, thereby forming a coating layer on the surface Sf of the substrate S.

In a period when the coating process is not performed on the stage 4 such as a period of transfer of the substrate S between the coater 1 and the substrate transporter 360 (a period of loading and unloading the substrate S), the nozzle 2 retreats into the nozzle adjustment region RA shifted toward the (+Y) direction from the holding surface 41 for the substrate S (a state shown in FIG. 3). Then, the nozzle maintenance unit performs various types of maintenance on the nozzle 2 in the nozzle adjustment region RA.

The configuration of the first standby unit 320 will be described next by referring back to FIGS. 1 and 2. The first standby unit 320 is provided next to the substrate loader/unloader 200. As shown in FIG. 2, the first standby unit 320 has internal space where a first mount 321 is provided that is configured to allow the substrate S to be placed thereon temporarily. Thus, by actuating the transport robot TR0 in response to a command from a controller for controlling the substrate loader/unloader 200, the substrate S stored in the cassette C is extracted and placed on the first mount 321. In this way, the substrate S before being subjected to the coating process and a predetermined pre-process and a predetermined post-process accompanying the coating process is temporarily put on standby. After being subjected to these processes described later, the substrate S is temporarily put on standby on the first mount 321. Then, the transport robot TR0 accesses the first mount 321 with appropriate timing, receives the substrate S, and returns the substrate S to the cassette C. In this way, the first standby unit 320 fulfills the function of transferring the substrate S smoothly between the substrate loader/unloader 200 and the substrate processing apparatus 300 and adjusting takt time between these apparatuses.

The pre-processing unit 330, the second standby unit 340, and the post-processing unit 350 are connected continuously in the (+X) direction with respect to the first standby unit 320. Of these units, the second standby unit 340 has a second mount 341 like the first standby unit 320. The second mount 341 is for temporarily putting the substrate S on standby after the substrate S is subjected to the pre-process by the pre-processing unit 330 or after the substrate S is subjected to the post-process by the post-processing unit 350 after implementation of the coating process on the substrate S. By doing so, the substrate S is transferred smoothly between the coating unit 310, the pre-processing unit 330, and the post-processing unit 350, and takt time is adjusted between these units.

The pre-processing unit 330 is arranged between the first standby unit 320 and the second standby unit 340. As shown in FIG. 1, the pre-processing unit 330 includes a housing 331 having an interior functioning as a part of the transport path TP, a heating tower 332 having a stack of heaters HPf for performing a dehydration baking process on the substrate S, and a cooling tower 333 having a stack of coolers CPf for cooling the substrate S after being subjected to the dehydration baking process. The housing 331 is provided next to the first mount 321. The heating tower 332 and the cooling tower 333 are arranged separately in the Y direction with respect to the housing 331. More specifically, the heating tower 332 is arranged in the (+Y) direction with respect to the housing 331 and the cooling tower 333 is arranged in the (−Y) direction with respect to the housing 331. A first transport robot TR1 is fixedly arranged in the housing 331. The first transport robot TR1 is configured in such a manner that a hand (not shown in the drawings) thereof available for holding the substrate S is accessible to the first mount 321, the heater HPf, the cooler CPf, and the second mount 341. Thus, by actuating the first transport robot TR1 in response to a command from a controller for controlling the substrate processing apparatus 300, the substrate S is moved back and forth along the transport path TP between the first mount 321 and the second mount 341 and is transported between the first mount 321, the heater HPf, the cooler CPf, and the second mount 341. In the present embodiment, the number of the heaters HPf in the heating tower 332 is “3” and the number of the coolers CPf in the cooling tower 333 is “3.” However, these numbers are not limited to “3” but are freely settable. The number of the heating towers 332 and that of the cooling towers 333 are also freely settable.

The post-processing unit 350 is arranged in the (+X) direction with respect to the second standby unit 340 with the second mount 341. As shown in FIG. 1, the post-processing unit 350 includes a housing 351 having an interior functioning as a part of the transport path TP, a vacuum drying tower 352 having a stack of vacuum dryers VD for performing a vacuum drying process on the substrate S after being subjected to the coating process, a heating tower 353 having a stack of heaters HPb for heating the substrate S after being subjected to the vacuum drying process, and a cooling tower 354 having a stack of coolers CPb for cooling the substrate S after being subjected to the heating process.

The housing 351 is provided between the second mount 341 and the coating unit 310. The vacuum drying tower 352, the heating tower 353, and the cooling tower 354 are arranged separately in the Y direction with respect to the housing 351. More specifically, the vacuum drying tower 352 is arranged in the (+Y) direction with respect to the housing 351, and the heating tower 353 and the cooling tower 354 are arranged in the (−Y) direction with respect to the housing 351. A second transport robot TR2 is arranged in the housing 351 in such a manner as to be movable in the X direction. The second transport robot TR2 is configured in such a manner that a hand (not shown in the drawings) thereof available for holding the substrate S is accessible to the second mount 341, the heater HPb, the cooler CPb, and the coater 1. Thus, by actuating the second transport robot TR2 in response to a command from the controller for controlling the substrate processing apparatus 300, the substrate S is moved back and forth along the transport path TP between the second mount 341 and the coater 1, and is transported between the second mount 341, the vacuum dryer VD, the heater HPb, the cooler CPb, and the coater 1.

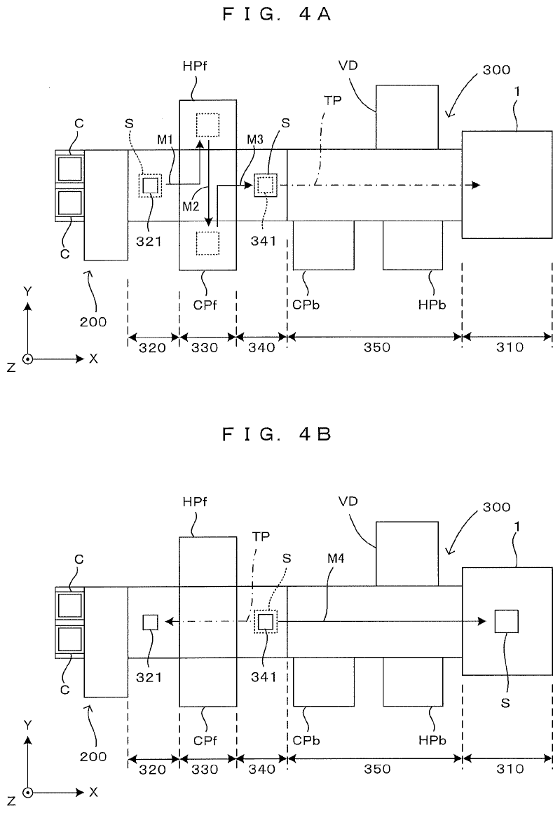

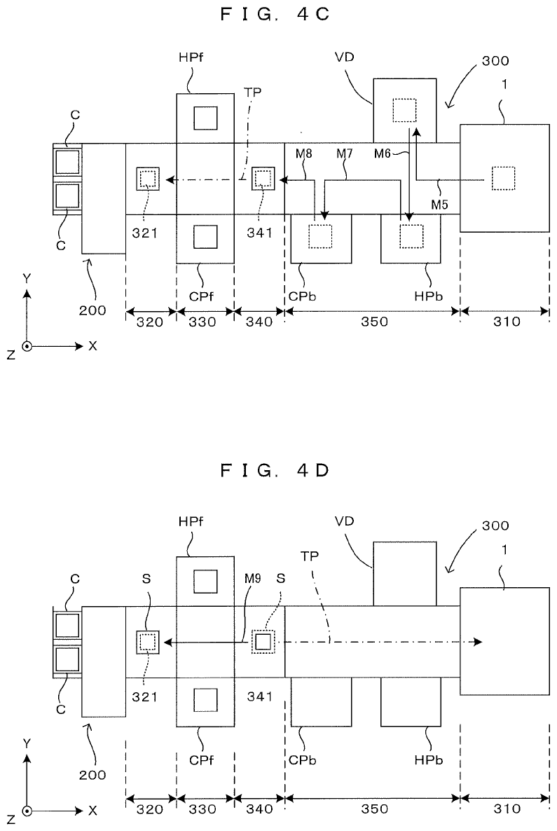

As described above, in the present embodiment, the first transport robot TR1 and the second transport robot TR2 are provided. The first transport robot TR1 and the second transport robot TR2 work in cooperation with each other to function as the substrate transporter 360, thereby transporting the substrate S received from the substrate loader/unloader 200 in the order described next and then transferring the substrate S to the substrate loader/unloader 200. The following describes transport of the substrate S and processes on the substrate S by the corresponding units in the substrate processing apparatus 300 by referring to FIGS. 4A to 4D. To facilitate understanding of the order of the transport and the processes, the transport and the processes will be described with attention focused on one substrate S.

FIGS. 4A to 4D are schematic views showing a procedure of the transport of the substrate and the processes on the substrate performed by the substrate processing apparatus in FIGS. 1 and 2. Signs M1 to M9 in these drawings indicate motions of transporting the substrate S.

In the substrate processing system 100, when the substrate loader/unloader 200 receives a command for loading the substrate S to be processed, a controller provided at the substrate loader/unloader 200 controls the transport robot TR0 to extract the unprocessed substrate S from the cassette C and places the extracted substrate S onto the first mount 321 of the substrate processing apparatus 300. Meanwhile, in the substrate processing apparatus 300, when a controller receives a command for starting a process on the substrate S put on standby on the first mount 321, the controller controls each part of the apparatus as described next. By doing so, the pre-process (dehydration baking process, cooling process), the coating process, and the post-process (vacuum drying process, post-baking process, cooling process) are performed on the substrate S, and then the substrate S is placed on the first mount 321 to be transferred to the substrate loader/unloader 200. Each of the processes is performed as follows.

As shown in FIG. 4A, the following motions are conducted in the pre-process. Specifically, the hand of the first transport robot TR1 receives the substrate S from the first mount 321, then accesses the heater HPf while keeping holding the substrate S, and transfers the substrate S to the heater HPf (motion M1). Next, the hand of the first transport robot TR1 retreats from the heater HPf and then the dehydration baking process is performed on the substrate S at the heater HPf.

When the heating process at the heater HPf is finished, the hand of the first transport robot TR1 accesses the heater HPf, receives the substrate S after being subjected to the dehydration baking process, and transports the substrate S to the cooler CPf (motion M2). Then, the hand of the first transport robot TR1 retreats from the cooler CPf. When the temperature of the substrate S is reduced thereafter to ordinary temperature by the cooler CPf, the hand of the first transport robot TR1 accesses the cooler CPf, receives the substrate S after being subjected to the dehydration baking process, and transports the substrate S to the second mount 341 (motion M3). By doing so, moisture (liquid component) is removed from the substrate S before implementation of the coating process by the coater 1 and the substrate S in this state is put on standby on the second mount 341 waiting for start of the coating process to be performed subsequently.

As shown in FIG. 4B, in the subsequent coating process, the second transport robot TR2 moves to a position facing the second mount 341. Next, the second transport robot TR2 receives the substrate S from the second mount 341, moves along the transport path TP to a position facing the coater 1 while keeping holding the substrate S with the hand, and stops temporarily at this position. Next, the second transport robot TR2 moves the hand holding the substrate S into the coater 1 and places the substrate S onto the stage 4 (see FIG. 3) (motion M4). At this time, the nozzle 2 has retreated relative to the stage 4 in the Y direction, thereby avoiding interference with the hand and the substrate S reliably. Next, the hand of the second transport robot TR2 retreats from the coater 1 and then the coating process is performed by the coater 1.

As shown in FIG. 4C, in the post-process performed subsequently, the second transport robot TR2 moves along the transport path TP to a position facing the coater 1, stops temporarily at this position, and then receives the substrate S after being subjected to the coating process from the coater 1. When the hand keeping holding the substrate S retreats from the coater 1, the second transport robot TR2 in this state moves along the transport path TP to a position facing the vacuum dryer VD and stops temporarily at this position. Next, the second transport robot TR2 moves the hand holding the substrate S into the vacuum dryer VD and transfers the substrate S to the vacuum dryer VD (motion M5). Next, the hand of the second transport robot TR2 retreats from the vacuum dryer VD and then the vacuum dryer VD performs the vacuum drying process as the post-process.

When the vacuum drying process is finished, the second transport robot TR2 moves along the transport path TP to a position facing the vacuum dryer VD and stops temporarily at this position. Next, the second transport robot TR2 moves the hand into the vacuum dryer VD and receives the substrate S. When the hand keeping holding the substrate S retreats from the vacuum dryer VD, the second transport robot TR2 in this state moves along the transport path TP to a position facing the heater HPb and stops temporarily at this position. Next, the second transport robot TR2 moves the hand holding the substrate S into the heater HPb and transfers the substrate S to the heater HPb (motion M6). Next, the hand of the second transport robot TR2 retreats from the heater HPb and then the heater HPb performs the post-baking process as the post-process.

When the post-baking process is finished, the second transport robot TR2 moves along the transport path TP to a position facing the heater HPb and stops temporarily at this position. Next, the second transport robot TR2 moves the hand into the heater HPb and receives the substrate S. When the hand keeping holding the substrate S retreats from the heater HPb, the second transport robot TR2 in this state moves along the transport path TP to a position facing the cooler CPb and stops temporarily at this position. Next, the second transport robot TR2 moves the hand holding the substrate S into the cooler CPb and transfers the substrate S to the cooler CPb (motion M7). Next, the hand of the second transport robot TR2 retreats from the cooler CPb and then the cooler CPb performs the cooling process as the post-process.

When the temperature of the substrate S is reduced thereafter to ordinary temperature by the cooler CPb, the second transport robot TR2 moves along the transport path TP to a position facing the cooler CPb and stops temporarily at this position. Next, the second transport robot TR2 moves the hand into the cooler CPb and receives the substrate S. When the hand keeping holding the substrate S retreats from the cooler CPb, the second transport robot TR2 in this state moves along the transport path TP to a position facing the second mount 341 and stops temporarily at this position. Next, the second transport robot TR2 moves the hand holding the substrate S to the second mount 341 to place the substrate S onto the second mount 341 (motion M8).

As shown in FIG. 4D, to make the substrate S unloadable from the substrate processing apparatus 300 after the substrate S is subjected to a series of the processes (including the pre-process, the coating process, and the post-process), the hand of the first transport robot TR1 accesses the second mount 341, receives the substrate S, and transfers the substrate S onto the first mount 321 as a different mount (motion M9). In this way, the processed substrate S is put on standby on the first mount 321 waiting to be transferred to the cassette C by the transport robot TR0 of the substrate loader/unloader 200.

As described above, in the present embodiment, the coater 1 is arranged face-to-face with the substrate loader/unloader 200 in the X direction (corresponding to a “first horizontal direction” of the present invention). The substrate S is transported back and forth along the transport path TP formed between the substrate loader/unloader 200 and the coater 1. Furthermore, the heater HPf and the cooler CPF for the pre-process, and the vacuum dryer VD, the heater HPb, and the cooler CPb for the post-process are arranged separately in the Y direction (corresponding to a “second horizontal direction” of the present invention) with respect to the transport path TP. Thus, the compactness of the substrate processing apparatus 300 is achieved in a horizontal plane. As a result, it is possible to reduce the footprint of the substrate processing apparatus 300 significantly to achieve reduction in energy required for substrate processing, the amount of usage of clean air, etc., thereby making large contribution to the SDGs.

In a substrate processing apparatus such as those of the suggested examples where a pre-processor, a coater, and a post-processor are arranged linearly, substrate loader/unloaders are required to be provided on both of a loading side and an unloading side of a substrate. This unavoidably results in cost increase and footprint enlargement of a substrate processing system. By contrast, in the substrate processing system 100 described above, the substrate loader/unloader 200 is required to be arranged only in the (−X) direction with respect to the substrate processing apparatus 300. Thus, the foregoing problems can be solved effectively.

In the above-described embodiment, the coater 1 is arranged in such a manner that the nozzle 2 of the coater 1 moves horizontally in a direction conforming to the Y direction that is perpendicular to a direction in which the transport path TP extends, namely, perpendicular to the X direction. This allows the substrate S to be loaded into and unloaded from the coater 1 while the nozzle 2 is out of an extension of the transport path TP. This certainly achieves shortening of time required for the loading and unloading, and further achieves shortening of time from loading of the substrate to start of the coating process and shortening of time from finish of the coating to start of unloading of the substrate. As a result, it is possible to shorten takt time required for the coating process.

While order of arrangement of the pre-processing unit 330 and the post-processing unit 350 in the X direction is determined freely, employing the arrangement order shown in FIG. 2 fulfills the following operation and effect. In a direction (corresponding to an “outward direction” of the present invention) defined as part of the X direction and pointing from the substrate loader/unloader 200 toward the coater 1, the post-processing unit 350 is arranged downstream from the pre-processing unit 330. Specifically, the post-processing unit 350 is arranged next to the coater 1. At a moment immediately after implementation of the coating process, a coating film has comparatively high fluidity so it desirably starts to be dried early. In this regard, as a result of a short distance from the coater 1 to the post-processing unit 350, it is possible to dry the coating film early so the coating film can be dried favorably.

In the above-described embodiment, the heater HPf and the cooler CPf correspond to examples of a “pre-processor” of the present invention, and correspond to an example of a “pre-heater” and an example of a “pre-cooler” of the present invention respectively. The vacuum dryer VD, the heater HPb, and the cooler CPb correspond to examples of a “post-processor” of the present invention. Of these units, the heater HPb and the cooler CPb correspond to an example of a “post-heater” and an example of a “post-cooler” of the present invention respectively. The first mount 321 and the second mount 341 correspond to an example of a “first standby part” and an example of a “second standby part” of the present invention respectively.

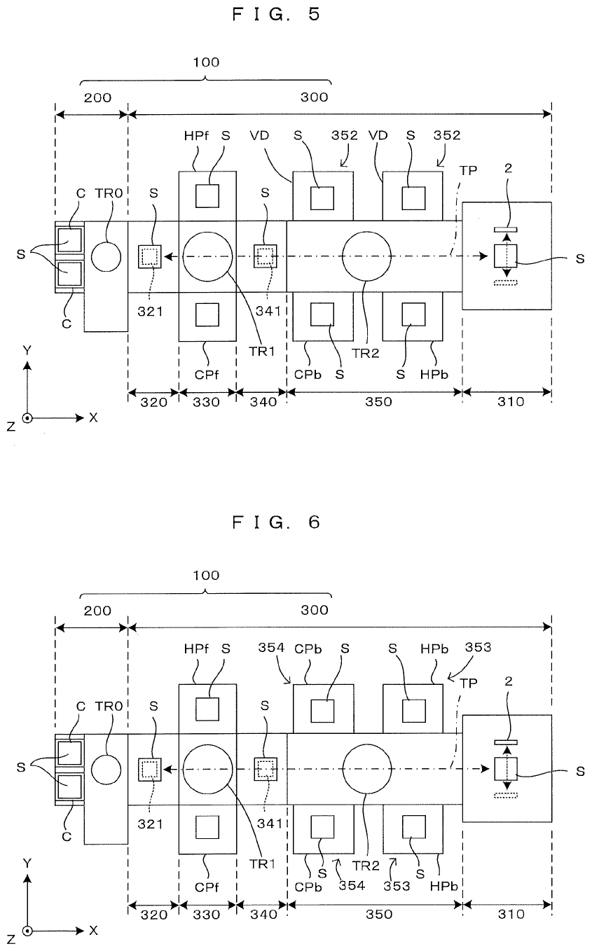

The present invention is not limited to the foregoing embodiment but can be changed in various ways other than those described above without departing from the purport of the invention. As an example, in the above-described embodiment, the pre-processor and the post-processor can be arranged in the (+Y) direction and the (−Y) direction with respect to the transport path TP. This makes it possible to provide the above-described towers additionally in response to time required for the dehydration baking process, the coating process, the reduced-pressure drying process, the post-baking process, and others. Referring to FIG. 1, for example, a region facing the cooling tower 354 across the transport path TP is empty. Thus, as shown in FIG. 5, for example, the reduced-pressure drying tower 352 may be provided additionally in response to takt time for the reduced-pressure drying process (second embodiment).

As shown in FIG. 6, for example, the heating tower 353 or the cooling tower 354 may be provided additionally instead of the reduced-pressure drying tower 352 (third embodiment). In this way, according to the layout employed herein, arrangements are freely separable in the Y direction across the transport path TP. This makes it possible to increase degrees of freedom in the configurations of the pre-processor and the post-processor, thereby obtaining a substrate processing apparatus and a substrate processing system with high general versatility.

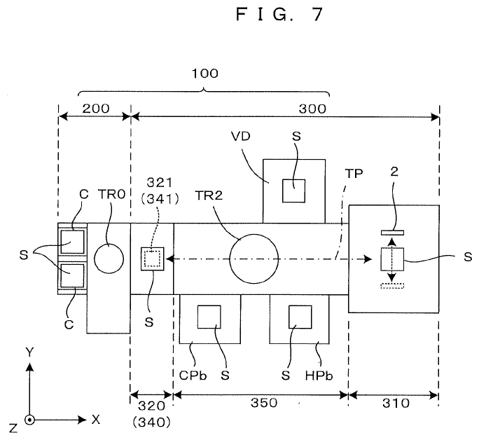

In many cases, the substrates S for semiconductor packages are made of resin and may absorb moisture at the time of loading from the substrate loader/unloader 200. In this regard, at the substrate processing apparatus 300 to apply a processing liquid to the substrates S for semiconductor packages, performing the dehydration baking process as the pre-process before implementation of the coating process like in the first to third embodiments is highly effective in increasing product quality. Meanwhile, if the substrate processing apparatus 300 is to apply a processing liquid to the substrate S having low moisture absorbency such as a glass substrate, the pre-processing unit 330 is omissible and one of the first mount 321 and the second mount 341 is omissible, as shown in FIG. 7 (fourth embodiment).

In the above-described embodiment, the substrate S is transferred between the substrate loader/unloader 200 and the substrate processing apparatus 300 via the first mount 321. Meanwhile, in one configuration, the substrate may be transferred directly between the transport robots.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

The present invention is applicable to every area of substrate processing technique that performs a coating process of applying a processing liquid to a substrate.

What is claimed is:

1. A substrate processing apparatus that performs a coating process of applying a processing liquid to a substrate received from a substrate loader/unloader, the apparatus comprising:
a coater configured to perform the coating process at a position separated from the substrate loader/unloader in a first horizontal direction;
a plurality of post-processors configured to perform a predetermined post-process on the substrate after being subjected to the coating process; and
a substrate transporter configured to transport the substrate back and forth in the first horizontal direction between the substrate loader/unloader and the coater along a transport path extending in the first horizontal direction, and configured to be responsive to each of the post-processors to stop temporarily at a position along the transport path and facing the post-processor and allow the substrate to be transferred to and from the post-processor, wherein
the post-processors are arranged separately with respect to the transport path in a second horizontal direction perpendicular to the first horizontal direction, and
the substrate transporter transports the substrate received from the substrate loader/unloader to the coater and then to the post-processors, and thereafter transfers the substrate to the substrate loader/unloader.

2. The substrate processing apparatus according to claim 1, wherein
the plurality of post-processors includes a post-heater that heats the substrate immediately after being subjected to the coating process, and a post-cooler that cools the substrate after being heated by the post-heater.

3. The substrate processing apparatus according to claim 1, wherein
the plurality of post-processors includes:
a vacuum dryer configured to dry a coating film under a reduced pressure immediately after the coating process, the coating film being a film of the processing liquid applied to the substrate;
a post-heater configured to heat the substrate after being dried under the reduced pressure by the vacuum dryer; and
a post-cooler configured to cool the substrate after being heated by the post-heater.

4. The substrate processing apparatus according to claim 1, further comprising:
a plurality of pre-processors configured to perform a predetermined pre-process on the substrate before being subjected to the coating process, wherein
the pre-processors are arranged separately with respect to the transport path and at positions different from the positions of the post-processors in the first horizontal direction,
the substrate transporter is configured to be responsive to each of the pre-processors to stop temporarily at a position along the transport path and facing the pre-processor and allow the substrate to be transferred to and from the pre-processor, and
the substrate transporter transports the substrate received from the substrate loader/unloader to the pre-processors before transporting the substrate to the coater.

5. The substrate processing apparatus according to claim 4, wherein
the plurality of pre-processors includes:
a pre-heater configured to heat the substrate before being transported to the coater; and
a pre-cooler configured to cool the substrate after being heated by the pre-heater.

6. The substrate processing apparatus according to claim 4, wherein
in an outward direction defined as part of the first horizontal direction and pointing from the substrate loader/unloader toward the coater, the post-processors are arranged downstream from the pre-processors.

7. The substrate processing apparatus according to claim 5, comprising:
a first standby part for putting the substrate on standby temporarily along the transport path and between the substrate loader/unloader and the pre-processors; and
a second standby part for putting the substrate on standby temporarily along the transport path and between the pre-processors and the post-processors, wherein
the substrate transporter includes:
a first transport robot configured to move the substrate back and forth along the transport path between the first standby part and the second standby part and configured to allow the substrate to be transported between the first standby part, the pre-processors, and the second standby part; and
a second transport robot configured to move the substrate back and forth along the transport path between the second standby part and the coater and configured to allow the substrate to be transported between the second standby part, the post-processors, and the coater.

8. A substrate processing system comprising:
a substrate loader/unloader configured to load and unload of a substrate; and
the substrate processing apparatus according to claim 1.
